(19) United States
(12) Patent Application Publication
(10) Pub. No.: US 2025/0204111 A1
(43) Pub. Date: Jun. 19, 2025

(54) SEMICONDUCTOR CHIP AND SEMICONDUCTOR DEVICE

(71) Applicant: Innolux Corporation, Miaoli County (TW)

(72) Inventors: Shu-Ming Kuo, Miaoli County (TW); Tsau-Hua Hsieh, Miaoli County (TW)

(73) Assignee: Innolux Corporation, Miaoli County (TW)

(21) Appl. No.: 18/950,216

(22) Filed: Nov. 18, 2024

Related U.S. Application Data
(60) Provisional application No. 63/611,214, filed on Dec. 18, 2023.
(60) Provisional application No. 63/609,351, filed on Dec. 13, 2023.

(30) Foreign Application Priority Data
Sep. 6, 2024 (CN) 202411250600.3

(51) Int. Cl. H01L 33/60; H01L 23/00; H01L 23/31; H01L 33/62

(52) U.S. Cl. CPC H10H 20/856; H01L 23/3135; H01L 24/08; H10H 20/857; H01L 2224/08225; H01L 2924/1811

(57) ABSTRACT

Disclosed is a semiconductor chip, including a semiconductor unit, a first electrode, a second electrode and a reflective layer. The semiconductor unit includes a semiconductor die and a filling layer. The semiconductor die includes a first-type semiconductor layer, an active layer and a second-type semiconductor layer stacked in sequence. The filling layer surrounds the semiconductor die. The first electrode is disposed on a first side of the semiconductor unit and electrically connected to the first-type semiconductor layer. The second electrode is disposed on a second side of the semiconductor unit and is electrically connected to the second-type semiconductor layer. A material of the second electrode includes a transparent conductive material. The reflective layer is disposed on a side surface of the filling layer. In a cross-sectional view, the side surface of the filling layer is connected to a top surface of the filling layer. A semiconductor device is also disclosed.

### CROSS-REFERENCE TO RELATED APPLICATION

This application claims the priority benefit of U.S. provisional application Ser. No. 63/611,214, filed on Dec. 18, 2023, U.S. provisional application Ser. No. 63/609,351, filed on Dec. 13, 2023, and China application serial no. 202411250600.3, filed on Sep. 6, 2024. The entirety of each of the above-mentioned patent applications is hereby incorporated by reference herein and made a part of this specification.

### BACKGROUND

### Field of the Disclosure

The present disclosure relates to a chip and an electronic device, and in particular, to a semiconductor chip and a semiconductor device.

### Description of Related Art

In horizontal-type semiconductor chips, the two electrodes (e.g., P-type electrode and N-type electrode) are situated on the same side of the chip, whereas in vertical-type semiconductor chips, the two electrodes are positioned on opposite sides (e.g., top and bottom sides) of the chip. Consequently, vertical-type semiconductor chips facilitate easier miniaturization of the chip area. However, subsequent to mass transfer, the design of vertical-type semiconductor chips, wherein the two electrodes are located on opposite sides of the chip, presents challenges in directly conducting electrical measurements, thereby impeding yield monitoring efforts.

### SUMMARY OF THE DISCLOSURE

The present disclosure provides a semiconductor chip and a semiconductor device, which facilitate the reduction of difficulties in electrical measurement.

In an embodiment of the disclosure, a semiconductor chip includes a semiconductor unit, a first electrode, a second electrode and a reflective layer. The semiconductor unit includes a semiconductor die and a filling layer. The semiconductor die includes a first-type semiconductor layer, an active layer and a second-type semiconductor layer stacked in sequence. The filling layer surrounds the semiconductor die. The first electrode is disposed on a first side of the semiconductor unit and is electrically connected to the first-type semiconductor layer. The second electrode is disposed on a second side of the semiconductor unit and is electrically connected to the second-type semiconductor layer. A material of the second electrode includes a transparent conductive material. The reflective layer is disposed on a side surface of the filling layer. In a cross-sectional view, the side surface of the filling layer is connected to a top surface of the filling layer.

In another embodiment of the present disclosure, a semiconductor device includes the aforementioned semiconductor chip and at least one light-converging element located above the semiconductor chip.

In order to make the above-mentioned features and advantages of the present disclosure more obvious and easy to understand, embodiments are given below and are described in detail below with reference to the accompanying drawings.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 and FIG. 3 are respectively schematic cross-sectional views of two semiconductor chips according to some embodiments of the present disclosure.

FIG. 2, FIG. 4, FIG. 5, FIG. 6, FIG. 7, FIG. 8 and FIG. 9 are respectively schematic cross-sectional views of seven semiconductor devices according to some embodiments of the present disclosure.

### DESCRIPTION OF EMBODIMENTS

Reference shall now be made in detail to exemplary embodiments of the present disclosure, examples of which are illustrated in the accompanying drawings. Where possible, the same reference numerals are used throughout the drawings and the description to refer to the same or like parts.

In the description of the disclosure and the appended claims, certain terms will be used to refer to specific elements. Persons skilled in the art would understand that electronic device manufacturers may refer to the same elements under different names. This disclosure does not intend to distinguish between elements that have the same functions but different names. In the following description and claims, the words “having” and “including” are open-ended words and thus should be interpreted as meaning “including but not limited to.”

The directional terminology employed herein, such as “upper,” “lower,” “front,” “rear,” “left,” and “right,” is utilized solely in reference to the orientation depicted in the accompanying figures. As such, the directional terminology is employed for descriptive purposes and is not intended to be limiting in nature. The figures illustrate typical features of methods, structures, and/or materials utilized in specific embodiments. However, these illustrations should not be construed as defining or limiting the scope or nature of the embodiments described herein. For instance, the relative dimensions, thicknesses, and positions of the various layers, regions, and/or structures may be reduced or enlarged for clarity of presentation.

In this disclosure, when one structure (or layer, component, substrate) is described as being on/above another structure (or layer, component, substrate), it may indicate that the two structures are adjacent and directly connected, or it may indicate that the two structures are adjacent but not directly connected. The absence of direct connection implies the presence of at least one intermediate structure (or intermediate layer, intermediate component, intermediate substrate, intermediate spacing) between the two structures, wherein the lower surface of one structure is adjacent to or directly connected to the upper surface of the intermediate structure, and the upper surface of the other structure is adjacent to or directly connected to the lower surface of the intermediate structure. The intermediate structure may be composed of single or multiple layers of physical or non-physical structures, without limitation. In this disclosure, when a certain structure is described as being “on” other structures, it may refer to the certain structure being “directly” on other structures, or it may refer to the certain structure being “indirectly” on other structures, meaning that there is at least one structure interposed between the certain structure and the other structures.

The terms “approximately,” “substantially,” or “about” are generally interpreted as within 10% of the given value or range, or alternatively interpreted as within 5%, 3%, 2%, 1%, or 0.5% of the given value or range. Furthermore, the phrases “ranging from a first value to a second value” or “in the range between a first value and a second value” indicate that the specified range includes the first value, the second value, and all values in between.

The ordinal numbers such as “first,” “second,” and so forth, employed in the specification and claims to modify components, do not in themselves imply or represent any prior ordinal sequence for said component(s), nor do they denote an order between one component and another, or a sequence in the manufacturing process. The utilization of such ordinal numbers serves solely to distinctly differentiate components bearing the same nomenclature. The terminology used in the claims need not correspond verbatim to that in the specification; consequently, a component referred to as the “first component” in the specification may be designated as the “second component” in the claims.

The electrical connections or couplings described in this disclosure may refer to either direct connections or indirect connections. In the case of direct connections, the terminals of components on two circuits are directly connected or interconnected by a conductive wire segment. In the case of indirect connections, there may be switches, diodes, capacitors, inductors, resistors, other suitable components, or combinations thereof, between the terminals of components on two circuits, but not limited thereto.

In this disclosure, the measurement of thickness, length, and width may be obtained through optical microscope (OM) measurement. Thickness or width may also be measured from cross-sectional images obtained through electron microscopy, but are not limited to these methods. Furthermore, a certain margin of error may exist between any two values or directions used for comparison. Moreover, the phrases “a given range from a first value to a second value,” “a given range falling within the range of a first value to a second value,” or “a given range between a first value and a second value” indicate that the aforementioned given range includes the first value, the second value, and all other values between them. If a first direction is perpendicular to a second direction, the angle between the first direction and the second direction may range from 80 degrees to 100 degrees. If a first direction is parallel to a second direction, the angle between the first direction and the second direction may range from 0 degrees to 10 degrees.

Unless otherwise defined, all terms (including technical and scientific terms) used herein shall have the same meaning as commonly understood by one of ordinary skill in the art to which this disclosure pertains. It is to be understood that terms such as those defined in commonly used dictionaries should be interpreted as having a meaning that is consistent with their meaning in the context of the relevant art and this disclosure, and should not be interpreted in an idealized or overly formal sense unless expressly so defined herein.

In the disclosure, the electronic device may include a semiconductor device, a display device, a backlight device, an antenna device, a packaging device, a sensing device, or a splicing device, but not limited thereto. The electronic device may be a bendable or flexible electronic device. The display device may be a non-self-luminous display device or a self-luminous display device. The display device may include, for example, liquid crystal, light-emitting diode, fluorescence, phosphor, quantum dot (QD), other suitable display media, or a combination of the foregoing. The antenna device may include, for example, a Reconfigurable Intelligent Surface (RIS), a Frequency Selective Surface (FSS), a radio frequency filter (RF-Filter), a polarizer, a resonator, or an antenna, etc. The antenna may be a liquid crystal antenna or a varactor diode antenna. The sensing device may be a sensing device that senses capacitance, light, heat energy or ultrasonic waves, but is not limited thereto. In the disclosure, the electronic device may include an electronic element. The electronic element may include a passive element and an active element, for example, a capacitor, a resistor, an inductor, a diode, a transistor, etc. Diodes may include light-emitting diodes, varactor diodes or photodiodes. The light-emitting diodes may include, for example, organic light-emitting diodes (OLEDs), submillimeter light-emitting diodes (mini LEDs), micro light-emitting diodes (micro LEDs) or quantum dot light-emitting diodes (quantum dot LED), but not limited thereto. The splicing device may be, for example, a display splicing device or an antenna splicing device, but is not limited thereto. It should be noted that the electronic device may be any combination of the above, but is not limited thereto. The packaging device may be suitable for Wafer-Level Package (WLP) technology or Panel-Level Package (PLP) technology, such as a packaging device for chip first process or chip last process. In addition, the shape of the electronic device may be a rectangular shape, a circular shape, a polygonal shape, a shape with curved edges, or other suitable shapes. Electronic devices may have peripheral systems such as driving systems, control systems, and light source systems to support display devices, antenna devices, wearable devices (for example, including augmented reality or virtual reality), vehicle-mounted devices (for example, including car windshields), or splicing devices.

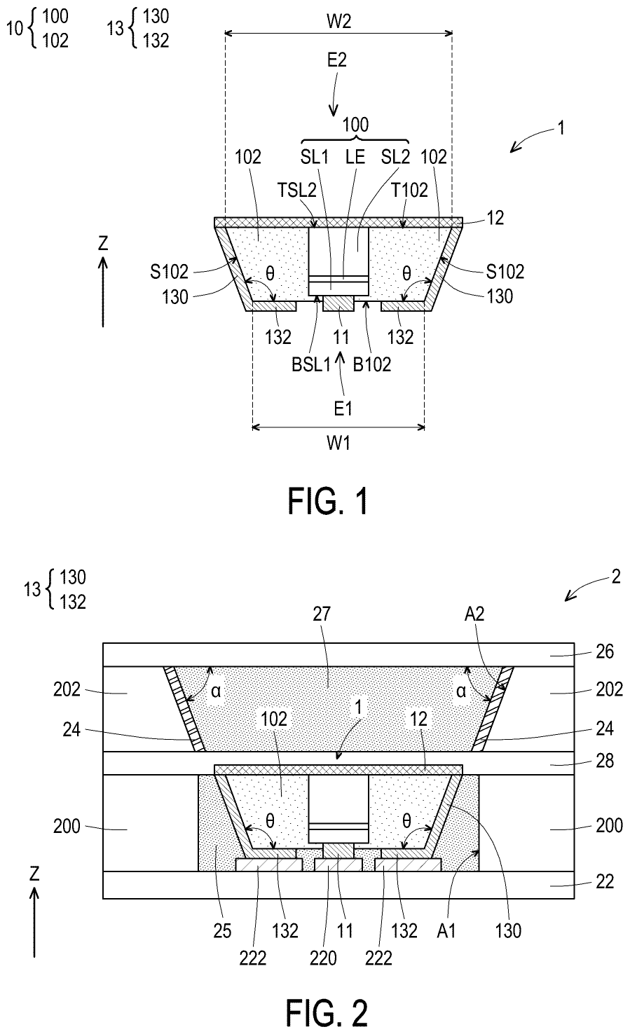

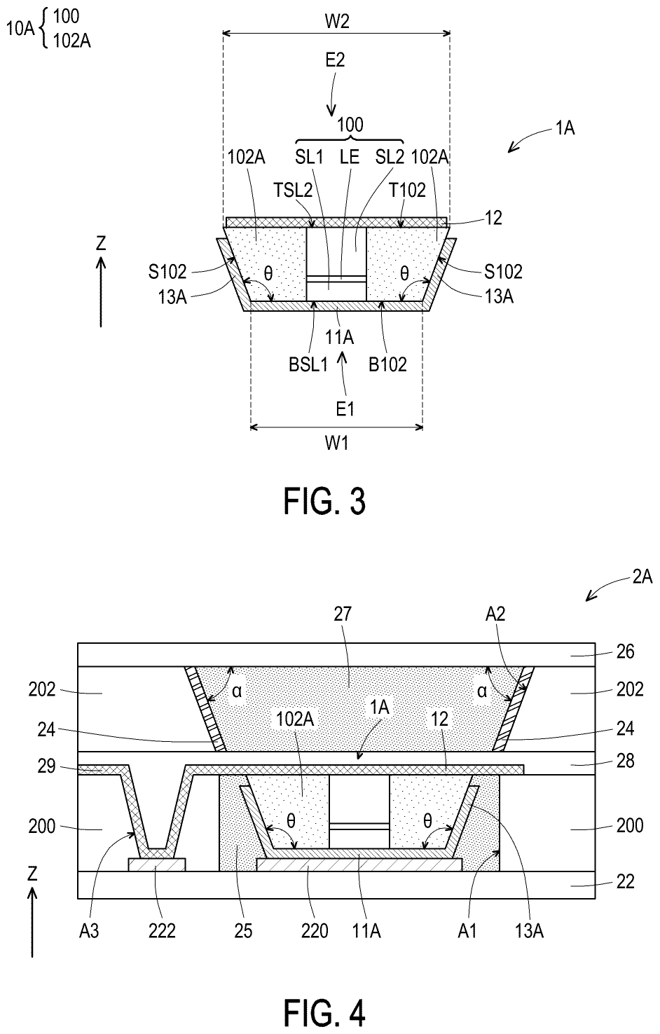

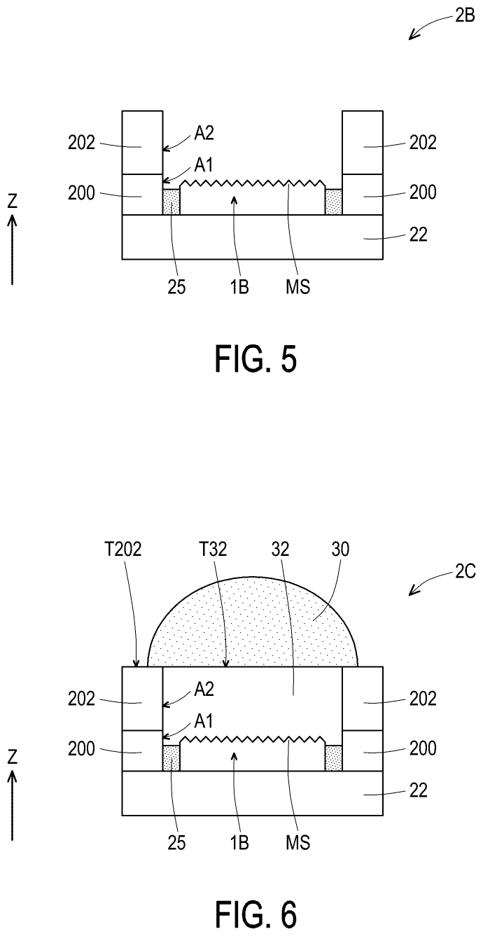

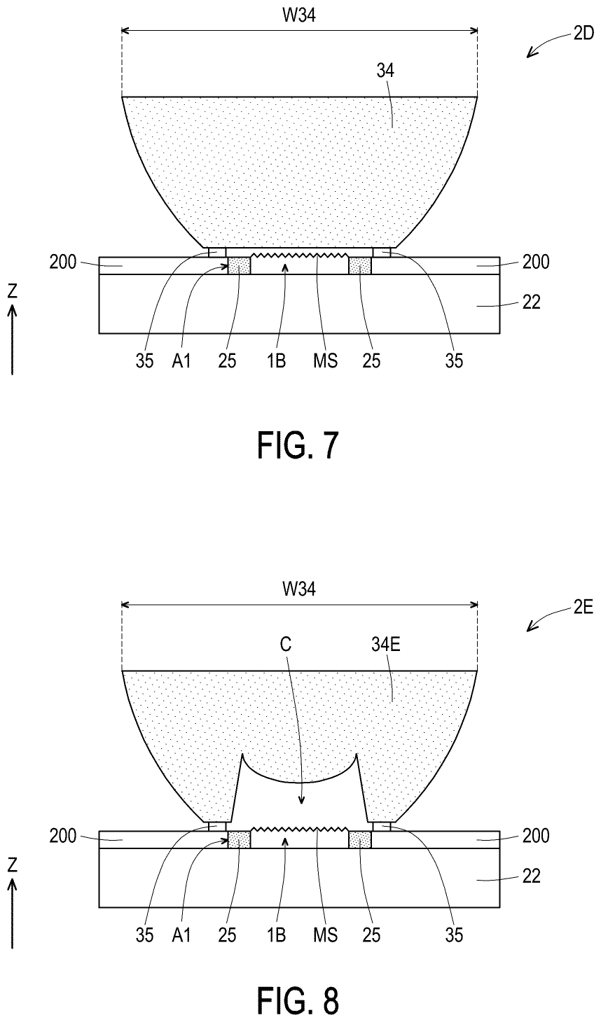

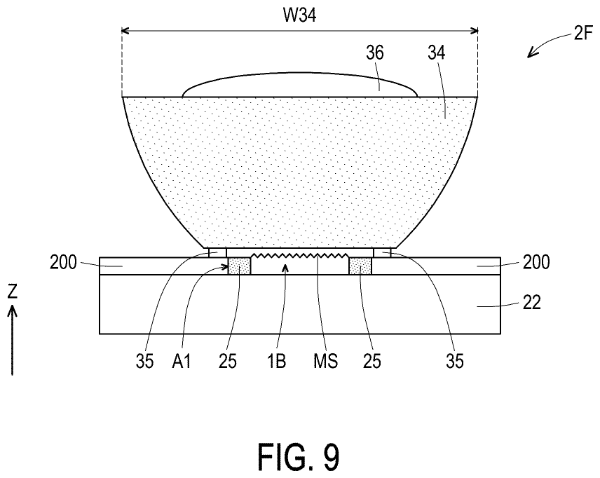

FIG. 1 and FIG. 3 are respectively schematic cross-sectional views of two semiconductor chips according to some embodiments of the present disclosure. FIG. 2, FIG. 4, FIG. 5, FIG. 6, FIG. 7, FIG. 8 and FIG. 9 are respectively schematic cross-sectional views of seven semiconductor devices according to some embodiments of the present disclosure. It should be noted that the following embodiments may be replaced, reorganized, and mixed with features of several different embodiments without departing from the spirit of the present disclosure to complete other embodiments. Features in various embodiments may be mixed and matched as long as they do not violate the spirit of the disclosure or conflict with each other.

Please refer to FIG. 1 first. The semiconductor chip 1 may include a semiconductor unit 10, a first electrode 11, a second electrode 12 and a reflective layer 13. The semiconductor unit 10 includes a semiconductor die 100 and a filling layer 102. The semiconductor die 100 includes a first-type semiconductor layer SL1, an active layer, such as a light-emitting layer LE, and a second-type semiconductor layer SL2 stacked in sequence. The filling layer 102 surrounds the semiconductor die 100. The first electrode 11 is disposed on the first side E1 of the semiconductor unit 10 (the lower side in FIG. 1) and is electrically connected to the first-type semiconductor layer SL1. The second electrode 12 is disposed on the second side E2 of the semiconductor unit 10 (the upper side in FIG. 1) and is electrically connected to the second-type semiconductor layer SL2. The material of the second electrode 12 includes a transparent conductive material. The reflective layer 13 is disposed on the side surface S102 of the filling layer 102. In the cross-sectional view, as shown in FIG. 1, the side surface S102 of the filling layer 102 is connected to the top surface T102 of the filling layer 102. In the present disclosure, the semiconductor device is for example a light emitting device, the semiconductor chip is for example a light-emitting chip, the semiconductor unit is for example a light-emitting unit, and the semiconductor die is for example a light-emitting diode.

Specifically, the semiconductor die 100 of the semiconductor unit 10 is configured to provide light, such as visible light or non-visible light, which may not be limited in the disclosure. In the semiconductor die 100, the first-type semiconductor layer SL1, the light-emitting layer LE and the second-type semiconductor layer SL2 are stacked sequentially, for example, along the thickness direction (for example, direction Z) of the semiconductor chip 1, that is, the light-emitting layer LE is located between the first-type semiconductor layer SL1 and the second-type semiconductor layer SL2.

The first-type semiconductor layer SL1 and the second-type semiconductor layer SL2 may be a P-type semiconductor layer and an N-type semiconductor layer respectively. Alternatively, the first-type semiconductor layer SL1 and the second-type semiconductor layer SL2 may be N-type semiconductor layer and P-type semiconductor layer, respectively. The light-emitting layer LE may include a quantum well layer or a multiple quantum well (MQW) layer, which may not be limited in the disclosure.

The filling layer 102 of the semiconductor unit 10 surrounds the semiconductor die 100. For example, the filling layer 102 may at least contact the side surface of the semiconductor die 100. For simplicity of the drawing, the side surface of the semiconductor die 100 is not shown in FIG. 1. The side surface of the semiconductor die 100 includes, for example, the side surface of the first-type semiconductor layer SL1, the side surface of the light-emitting layer LE, and the side surface of the second-type semiconductor layer SL2.

The filling layer 102 may expose at least part of the bottom surface BSL1 of the first-type semiconductor layer SL1 to facilitate the electrical connection between the first-type semiconductor layer SL1 and the first electrode 11. For example, the first electrode 11 may be disposed on the bottom surface BSL1 exposed by the filling layer 102, but not limited thereto. In some embodiments, as shown in FIG. 1, the filling layer 102 may cover a partial bottom surface BSL1 of the first-type semiconductor layer SL1 such that the bottom surface B102 of the filling layer 102 is lower than the bottom surface BSL1 of the first-type semiconductor layer SL1, however, this disclosure is not limited thereto.

The filling layer 102 may expose at least part of the top surface TSL2 of the second-type semiconductor layer SL2 to facilitate the electrical connection between the second-type semiconductor layer SL2 and the second electrode 12. For example, the second electrode 12 may be disposed on the top surface TSL2 exposed by the filling layer 102, but not limited thereto. In some embodiments, as shown in FIG. 1, the top surface T102 of the filling layer 102 may be aligned with the top surface TSL2 of the second-type semiconductor layer SL2. In the embodiment in which the second electrode 12 is further disposed on the top surface T102 of the filling layer 102, as shown in FIG. 1, the design that the top surface T102 of the filling layer 102 is aligned with the top surface TSL2 of the second-type semiconductor layer SL2 helps to reduce the probability of disconnection of the second electrode 12 caused by surface discontinuity. It should be noted that the filling layer 102 can be a single-layer structure or a multi-layer structure.

The side surface S102 of the filling layer 102, for example, connects the top surface T102 of the filling layer 102 and the bottom surface B102 of the filling layer 102, and the side surface S102 of the filling layer 102 is configured to carry the reflective layer 13. In some embodiments, the cross-sectional shape of the filling layer 102 may be approximately an inverted trapezoid with a hollow center. For example, in the cross-sectional view, as shown in FIG. 1, the semiconductor unit 10 has a first width W1 and a second width W2 on the first side E1 and the second side E2 respectively, and the second width W2 is greater than the first width W1. In addition, the angle θ between the side surface S102 and the bottom surface B102 of the filling layer 102 is, for example, greater than or equal to 100 degrees and less than or equal to 170 degrees, or greater than or equal to 110 degrees and less than or equal to 150 degrees. By changing the included angle θ, the inclination angle of the reflective layer 13 disposed on the side surface S102 of the filling layer 102 may be changed, thereby improving the light extraction efficiency, changing the light pattern or light intensity distribution of the light emitted from the semiconductor unit 10, etc.

The material of the filling layer 102 may be selected from a light-transmitting dielectric material to reduce the loss of light propagating in the filling layer 102. For example, the material of the filling layer 102 may include acrylic material, siloxane material, photoresist, silica or other materials with a transmittance greater than 80% or even 90%. For example, when the semiconductor die 100 provides visible light (for example, light with a wavelength of 400 nm to 700 nm), the filling layer 102 may be made of a material with a transmittance of visible light greater than 80% or even 90%.

The first electrode 11 is, for example, disposed on the bottom surface BSL1 of the first-type semiconductor layer SL1 and contacts the bottom surface BSL1 of the first-type semiconductor layer SL1. In some embodiment, there is an ohmic contact layer disposed between the first-type semiconductor layer SL1 and the first electrode 11. The ohmic contact layer may include metal oxides. Metal oxides may include indium tin oxide, indium zinc oxide, aluminum tin oxide, aluminum zinc oxide, indium germanium zinc oxide, or other metal oxides. In some embodiments, the material of the first electrode 11 may include silver, aluminum, or other metals and/or alloys with high reflectivity, such as metals or alloys with a reflectivity higher than 60% for visible light, but the disclosure is not limited thereto. In other embodiments, the material of the first electrode 11 may include gold, copper or other metals and/or alloys with high conductivity, and the inner side of the metal and/or alloy with high conductivity (close to one side of the semiconductor unit 10) may be formed with a non-conductive reflective layer, such as a distributed Bragg reflector (DBR), but is not limited thereto.

The second electrode 12 is, for example, disposed on the top surface TSL2 of the second-type semiconductor layer SL2 and the top surface T102 of the filling layer 102 and contacts the top surface TSL2 of the second-type semiconductor layer SL2 and the top surface T102 of the filling layer 102. In some embodiment, there is an ohmic contact layer disposed between the second-type semiconductor layer SL2 and the second electrode 12. The material of the second electrode 12 includes a transparent conductive material so that light is able to pass through the second electrode 12. The transparent conductive material may include metal oxides, graphene, other suitable transparent conductive materials, or combinations thereof. Metal oxides may include indium tin oxide, indium zinc oxide, aluminum tin oxide, aluminum zinc oxide, indium germanium zinc oxide, or other metal oxides. Alternatively, the transparent conductive material may include a thin metal or metal mesh, for example, a very thin metal layer (e.g., magnesium layer or silver layer) may be formed, or the metal mesh layer with light-transmitting openings may be formed through a screen printing or other patterning process to allow light to pass through the second electrode 12.

The reflective layer 13 is configured to reflect light so that the semiconductor chip 1 may emit more light. In some embodiments, the reflective layer 13 may be further configured as an extension electrode of the second electrode 12, and the bonding end of the second electrode 12 is moved to a side where the first electrode 11 is located (such as the first side E1) through the reflective layer 13 to form a flip-chip bonding structure, which helps reduce the difficulty of electrical measurement after mass transfer, making yield monitoring easier. As shown in FIG. 1, the second electrode 12 may be electrically connected to the reflective layer 13. For example, the second electrode 12 may further extend to the reflective layer 13 and be connected to the reflective layer 13, but is not limited thereto. In addition, the reflective layer 13 may include a first portion 130 and a second portion 132, wherein the first portion 130 is disposed on the side surface S102 of the filling layer 102, and the second portion 132 is disposed on the bottom surface B102 of the filling layer 102. The second electrode 12 may be disposed on the top surface TSL2 of the second-type semiconductor layer SL2 and the top surface T102 of the filling layer 102 and connected to the first portion 130. The second portion 132 is separated from the first electrode 11 to maintain independent electrical properties, and the second portion 132 may be electrically connected to the second electrode 12 through the first portion 130. In some embodiments, the reflective layer 13 and the first electrode 11 may include the same material and are made through the same photolithography process.

The angle between the first portion 130 and the second portion 132 is equal to or approximately the angle θ between the side surface S102 and the bottom surface B102 of the filling layer 102. In some embodiments, the included angle (included angle θ) between the first portion 130 and the second portion 132 is, for example, greater than or equal to 100 degrees and less than or equal to 170 degrees, or greater than or equal to 110 degrees and less than or equal to 150 degrees. In addition, the material of the reflective layer 13 may include silver, aluminum, tin, indium, gold or a combination of the above, but is not limited thereto.

FIG. 2 is a semiconductor device 2 including the semiconductor chip 1 of FIG. 1. Please refer to FIG. 2. In addition to the semiconductor chip 1, the semiconductor device 2 may also include at least one light-converging element located above the semiconductor chip 1. Taking FIG. 2 as an example, the at least one light-converging element may be a combination of a reflective layer 24, a filling layer 27 and a bank layer 202. In some embodiments, as shown in FIG. 2, the semiconductor device 2 may further include a circuit substrate 22, wherein the semiconductor chip 1 and the at least one light-converging element (for example, the reflective layer 24, the filling layer 27 and the bank layer 202) is disposed on the circuit substrate 22, and the circuit substrate 22 includes a first pad 220 electrically connected to the first electrode 11 and a second pad 222 electrically connected to the second electrode 12. The materials of the first pad 220 and the second pad 222 may include gold, tin, indium, copper or other suitable conductive materials.

In some embodiments, as shown in FIG. 2, the semiconductor device 2 may further include a unit defining layer 200. The unit defining layer 200 is located on the circuit substrate 22 and has a first opening A1. The semiconductor chip 1 is located in the first opening A1. The bank layer 202 is located on the unit defining layer 200 and has a second opening A2 overlapping the first opening A1. The material of the unit defining layer 200 and the bank layer 202 may include organic photoresist, and the color of the unit defining layer 200 and the bank layer 202 may be transparent, black, white or other colors, but is not limited thereto. In some embodiments, a reflective layer 24 may be formed on the inner wall of the bank layer 202 to improve light extraction efficiency. The material of the reflective layer 24 may include silver, aluminum, or other materials with high reflectivity (e.g., distributed Bragg reflectors). In some embodiments, the filling layer 27 is disposed in the second opening A2. Regarding the material of the filling layer 27, please refer to the material of the filling layer 102 for reference, and related details will not be repeated here.

In some embodiments, as shown in FIG. 2, the first pad 220 and the second pad 222 are located in the first opening A1, the second electrode 12 is also disposed on the top surface T102 of the filling layer 102, and the second electrode 12 may be electrically connected to the second pad 222 through the reflective layer 13. Specifically, when the semiconductor chip 1 is bonded to the circuit substrate 22, the first pad 220 and the second pad 222 may be bonded to the first electrode 11 and the second portion 132 of the reflective layer 13 respectively, and the second electrode 12 may be electrically connected to the second pad 222 through the first portion 130 and the second portion 132. Since the second portion 132 and the first electrode 11 are located on the same side (for example, the lower side) of the semiconductor chip 1, it is possible to help reduce the difficulty of electrical measurement after mass transfer, making yield monitoring easier.

In some embodiments, as shown in FIG. 2, the semiconductor device 2 may further include a filling layer 25, a substrate 26 and an adhesive layer 28, but is not limited thereto. According to different requirements, one or more components or layers may be added to or reduced from the semiconductor device 2.

The filling layer 25 is disposed in the first opening A1. The filling layer 25 may improve the adhesion between the semiconductor chip 1 and the circuit substrate 22. Regarding the material of the filling layer 25, please refer to the material of the filling layer 102 for reference, and related details will not be repeated here.

The substrate 26 is a light-transmitting substrate, and the substrate 26 may be configured to carry the at least one light-converging element (for example, including the bank layer 202, the reflective layer 24 and the filling layer 27). Specifically, the bank layer 202, the reflective layer 24 and the filling layer 27 may be formed on the substrate 26 and then bonded to the circuit substrate 22 through the adhesive layer 28. The substrate 26 may be a rigid substrate or a flexible substrate. The material of the substrate 26 includes, for example, glass, quartz, ceramic, sapphire or plastic, but is not limited thereto. Plastics may include polycarbonate (PC), polyimide (PI), polypropylene (PP), polyethylene terephthalate (PET), and other suitable flexible materials or combinations of the aforementioned materials, but not limited thereto. The material of the adhesive layer 28 may include optical clear adhesive (OCA) or optical clear resin (OCR), but is not limited thereto.

In some embodiments, the angle α between the substrate 26 and the reflective layer 24 is, for example, greater than or equal to 10 degrees and less than or equal to 80 degrees, or greater than or equal to 30 degrees and less than or equal to 70 degrees. By changing the included angle α, the inclination angle of the reflective layer 24 may be changed, thereby improving the light extraction efficiency, changing the light pattern or light intensity distribution of the light emitted from the semiconductor device 2, and so on.

In other embodiments, although not shown, the bank layer 202 may be directly formed on the unit defining layer 200. In this way, the semiconductor device 2 may not include the adhesive layer 28 and the substrate 26. Optionally, the at least one light-converging element may not include the filling layer 27.

According to a simulation result, compared with the conventional semiconductor chip, the design of the semiconductor chip 1 helps to increase the luminous brightness from 100% to greater than 250% and reduces the angle of the half-maximum full width of the light pattern from ±65° to ±35°, and the design of the semiconductor chip 1 along with the at least one light-converging element helps to increase the luminous brightness from 100% to greater than 550% and reduce the half-maximum full width of the light pattern from ±65° to ±25°.

Please refer to FIG. 3. The main differences between the semiconductor chip 1A and the semiconductor chip 1 of FIG. 1 are described below. In the semiconductor chip 1A, the second electrode 12 and the reflective layer 13A are electrically insulated from each other. For example, the second electrode 12 and the reflective layer 13A may be separated from each other to maintain independent electrical properties. In addition, the first electrode 11A is disposed, for example, on the bottom surface BSL1 of the first-type semiconductor layer SL1 and the bottom surface B102 of the filling layer 102A and is connected to the reflective layer 13A. In some embodiments, the first electrode 11A and the reflective layer 13A may be formed together, for example, using the same material and the same process, but are not limited thereto. In other embodiments, the first electrode 11A and the reflective layer 13A may be formed separately. The included angle between the first electrode 11A and the reflective layer 13A is equal to or approximately the included angle θ between the side surface S102 and the bottom surface B102 of the filling layer 102A. In some embodiments, the included angle (included angle θ) between the first electrode 11A and the reflective layer 13A is, for example, greater than or equal to 100 degrees and less than or equal to 170 degrees, or greater than or equal to 110 degrees and less than or equal to 150 degrees. In some embodiments, as shown in FIG. 2, the filling layer 102A may expose the entire bottom surface BSL1 of the first-type semiconductor layer SL1, and the bottom surface B102 of the filling layer 102A may be aligned with the bottom surface BSL1 of the first-type semiconductor layer SL1, thus reducing the probability of disconnection of the first electrode 11A caused by surface discontinuity. In some embodiments, although not shown, the second electrode 12 is connected to the reflective layer 13A, the reflective layer 13A does not extend to the bottom surface B102 of the filling layer 102A, and the reflective layer 13A is not connected to the first electrode 11A. In the above embodiment, the semiconductor chip 1A is still a vertical type semiconductor chip and is not transformed into a horizontal type semiconductor chip through the reflective layer 13A.

FIG. 4 is a semiconductor device 2A including the semiconductor chip 1A of FIG. 3. Please refer to FIG. 4. The main differences between the semiconductor device 2A and the semiconductor device 2 of FIG. 2 are described below. In the semiconductor device 2A, the first pad 220 is located in the first opening A1, and the unit defining layer 200 further has a third opening A3 that partially exposes the second pad 222. The semiconductor device 2A further includes a connecting wire 29 located on the unit defining layer 200 and in the third opening A3, and the second electrode 12 is electrically connected to the second pad 222 through the connecting wire 29. Specifically, when the semiconductor chip 1A is bonded to the circuit substrate 22, the first pad 220 and the second pad 222 may be bonded to the first electrode 11A and the connecting wire 29 respectively, and the second electrode 12 may be electrically connected to the second pad 222 through the connecting wire 29. In some embodiments, the second electrode 12 and the connecting wire 29 may be formed together, for example, using the same material and the same process, but are not limited thereto.

FIG. 5 to FIG. 9 are schematic cross-sectional views of various semiconductor devices according to other embodiments of the present disclosure. In FIG. 5 to FIG. 9, for the simplicity of the drawings, the first pad 220 and the second pad 222 are omitted, and the detailed structure of the semiconductor chip 1B and the details of the electrical connection between the semiconductor chip 1B and the circuit substrate 22 are omitted. According to different needs, the semiconductor chip 1B in FIG. 5 to FIG. 9 may adopt the aforementioned semiconductor chip 1 or semiconductor chip 1A, and the details of the electrical connection between the semiconductor chip 1B and the circuit substrate 22 may be derived from FIG. 2 or FIG. 4, and related details will not be repeated here.

Please refer to FIG. 5. The main differences between the semiconductor device 2B and the aforementioned semiconductor device 2 or the semiconductor device 2A are described below. The semiconductor device 2B does not include the substrate 26, the filling layer 27 and the adhesive layer 28 of FIG. 2 or FIG. 4. In addition, a plurality of microstructures MS are formed on the semiconductor surface of the semiconductor chip 1B (e.g., the top surface of the semiconductor chip 1B). The plurality of microstructures MS are formed, for example, by roughening or patterning the top of the semiconductor chip 1B, but are not limited thereto. In some embodiment, the plurality of microstructures MS are formed in the epitaxial growth on a pattern sapphire substrate.

In other embodiments, although not shown, the unit defining layer 200 and the bank layer 202 may be replaced with a single-layer structure. For example, the single-layer structure may be composed of a single-layer photoresist layer, and the single-layer photoresist layer may be formed with an opening for accommodating the semiconductor chip 1B. The following embodiments may all be modified accordingly, and will not be repeated below. In some embodiment, the unit defining layer 200 and the bank layer 202 are reflective.

According to a simulation result, compared with arranging the semiconductor chip directly on the circuit substrate, in this embodiment, by arranging a unit defining layer 200 and a bank layer 202 around the semiconductor chip 1B, the brightness may be increased from 100% to 161% and the luminous flux may be increased from 100% to 108%.

Please refer to FIG. 6. The main differences between the semiconductor device 2C and the semiconductor device 2B of FIG. 5 are described below. In the semiconductor device 2C, the at least one light-converging element further includes a lens element 30, and the lens element 30 is disposed above the bank layer 202 and the semiconductor chip 1B. The material of the lens element 30 may include photoresist, and the lens element 30 may be formed by molding, exposure and development, or imprinting, but is not limited thereto. In some embodiments, a filling layer 32 may be disposed on the filling layer 25 and the semiconductor chip 1B and located in the first opening A1 and the second opening A2. The top surface T32 of the filling layer 32 may be aligned with the top surface T202 of the bank layer 202 to provide a plane for carrying the lens element 30. Description of the material of the filling layer 32 may be derived from the material of the filling layer 25 and will not be repeated here.

In other embodiments, although not shown, a single filling layer may be adopted to replace the filling layer 25 and the filling layer 32.

Through the arrangement of the lens element 30, refraction may be used to narrow or converge the light emitted from the semiconductor device 2C, thereby increasing the brightness of the semiconductor device 2C or reducing the divergence angle of the light. According to a simulation result, compared with arranging the semiconductor chip directly on the circuit substrate, in this embodiment, by disposing at least one light-converging element (for example, the filling layer 32, the bank layer 202 and the lens element 30) above the semiconductor chip 1B, and disposing a unit defining layer 200 around the semiconductor chip 1B, the brightness may be increased from 100% to 277% and the luminous flux may be increased from 100% to 103%.

Please refer to FIG. 7. The main differences between the semiconductor device 2D and the semiconductor device 2B of FIG. 5 are described below. The semiconductor device 2D does not include the bank layer 202 and the filling layer 25 which fill the first opening A1 that is not occupied by the semiconductor chip 1B. The at least one light-converging element includes a reflective cup element 34, and the reflective cup element 34 is disposed above the unit defining layer 200 and the semiconductor chip 1B. For example, the semiconductor device 2D may further include an adhesive layer 35, and the reflective cup element 34 may be bonded to the unit defining layer 200 through the adhesive layer 35, but is not limited thereto. In other embodiments, the reflective cup element 34 may be fixed on the unit defining layer 200 through other fixing mechanisms (e.g., fitting structures or other mechanical components). The reflective cup element 34 may be a parabolic reflective cup, but is not limited thereto. The material of the reflective cup element 34 may include acrylic resin, but is not limited thereto. The description of the material of the adhesive layer 35 may be derived from the material of the adhesive layer 28 and will not be repeated here.

Through the arrangement of the reflective cup element 34, refraction may be adopted to narrow or converge the light emitted from the semiconductor device 2D, thereby increasing the brightness of the semiconductor device 2D, reducing the divergence angle of the light, or changing the light pattern. In some embodiments, the brightness or light pattern may be changed by adjusting the maximum width W34 of the reflective cup element 34. For example, the maximum width W34 of the reflective cup element 34 may be 100 micrometers (μm) or 150 μm, but is not limited thereto. According to a simulation result, compared with arranging the semiconductor chip directly on the circuit substrate, in this embodiment, by disposing at least one light-converging element (for example, the reflective cup element 34) above the semiconductor chip 1B, and disposing a unit defining layer 200 around the semiconductor chip 1B, the brightness may be increased from 100% to 984% and the luminous flux may be increased from 100% to 245%. In addition, if the maximum width W34 of the reflective cup element 34 is increased (for example, the maximum width W34 is increased from 100 μm to 150 μm), the brightness may be increased from 100% to 2507% and the luminous flux may be increased from 100% to 180%.

Please refer to FIG. 8. The main differences between the semiconductor device 2E and the semiconductor device 2D of FIG. 7 are described below. In the semiconductor device 2E, the surface of the reflective cup element 34E facing the semiconductor chip 1B has a cavity C that overlaps the semiconductor chip 1B. The cavity C contains air, for example.

The design of the cavity C may reduce the probability that the light emitted from the semiconductor chip 1B is directly emitted out of the reflective cup element 34E, and the refraction and reflection may be adopted to effectively converge the light, thereby improving the brightness of the semiconductor device 2D. According to a simulation result, compared with arranging the semiconductor chip directly on the circuit substrate, in this embodiment, by disposing at least one light-converging element (for example, the reflective cup element 34E) above the semiconductor chip 1B, and disposing a unit defining layer 200 around the semiconductor chip 1B, the brightness may be increased from 100% to 1344% and the luminous flux may be increased from 100% to 250%.

Please refer to FIG. 9. The main differences between the semiconductor device 2F and the semiconductor device 2D of FIG. 7 are described below. In the semiconductor device 2F, the at least one light-converging element further includes a lens element 36, and the lens element 36 is disposed on the reflective cup element 34. The description of the material of the lens element 36 may be derived from the material of the lens element 30 mentioned above and will not be repeated here.

The design of arranging the lens element 36 on the reflective cup element 34 may not only further improve the brightness of the semiconductor device 2F, but also help to reduce the overall area of the light-converging element, making the light-converging element to be more suitable for high-resolution products. According to a simulation result, compared with arranging the semiconductor chip directly on the circuit substrate, in this embodiment, by disposing at least one light-converging element (for example, the reflective cup element 34 and lens element 36) above the semiconductor chip 1B, and disposing a unit defining layer 200 around the semiconductor chip 1B, the brightness may be increased from 100% to 4666% and the luminous flux may be increased from 100% to 178%.

In light of the foregoing, in the disclosed embodiment herein, through the coordinated arrangement of the filling layer, the first electrode, the second electrode, and the reflective layer, the bonding terminals of the semiconductor chip are positioned on the same side of the semiconductor chip. This configuration serves to reduce the difficulty of electrical measurements subsequent to mass transfer, thereby facilitating yield monitoring.

The foregoing embodiments are provided solely for the purpose of illustrating the technical solutions disclosed herein and are not intended to be limiting. Although the disclosure has been described in detail with reference to the preceding embodiments, those skilled in the art should understand that: they may still modify the technical solutions described in the preceding embodiments, or substitute equivalent alternatives for part or all of the technical features thereof. Such modifications or substitutions do not cause the corresponding technical solutions to deviate from the scope of the technical solutions of the embodiments of this disclosure.

Although the embodiments and advantages of this disclosure have been described as above, it should be understood that those skilled in the art may make modifications, substitutions, and refinements without departing from the spirit and scope of this disclosure. Features between embodiments may be arbitrarily mixed and replaced to form other new embodiments. Furthermore, the scope of protection of this disclosure is not limited to the specific processes, machines, manufacturing, material compositions, devices, methods, and steps described in the specification. Any person skilled in the art can understand from the content disclosed herein current or future developed processes, machines, manufacturing, material compositions, devices, methods, and steps that can be implemented in the embodiments described herein to achieve substantially the same function or obtain substantially the same result, all of which can be used according to this disclosure. Therefore, the scope to be protected by this disclosure includes the aforementioned processes, machines, manufacturing, material compositions, devices, methods, and steps. Additionally, each claim constitutes a separate embodiment, and the scope to be protected by this disclosure also includes combinations of individual claims and embodiments. The scope to be protected by this disclosure shall be governed by the accompanying claims.

What is claimed is:

1. A semiconductor chip, comprising:
a semiconductor unit comprising:
a semiconductor die comprising a first-type semiconductor layer, an active layer and a second-type semiconductor layer stacked in sequence; and
a filling layer surrounding the semiconductor die;
a first electrode disposed on a first side of the semiconductor unit and electrically connected to the first-type semiconductor layer;
a second electrode disposed on a second side of the semiconductor unit and electrically connected to the second-type semiconductor layer, wherein a material of the second electrode comprises a transparent conductive material; and
a reflective layer disposed on a side surface of the filling layer, wherein in a cross-sectional view, the side surface of the filling layer is connected to a top surface of the filling layer.

2. The semiconductor chip according to claim 1, wherein the second electrode is electrically connected to the reflective layer.

3. The semiconductor chip according to claim 2, wherein the reflective layer further comprises:
a first portion disposed on the side surface of the filling layer; and
a second portion disposed on a bottom surface of the filling layer.

4. The semiconductor chip according to claim 3, wherein an angle between the first portion and the second portion is greater than or equal to 100 degrees and less than or equal to 170 degrees.

5. The semiconductor chip according to claim 3, wherein the second electrode is disposed on a top surface of the second-type semiconductor layer and the top surface of the filling layer and is connected to the first portion.

6. The semiconductor chip according to claim 1, wherein the second electrode is electrically insulated from the reflective layer.

7. The semiconductor chip according to claim 6, wherein an angle between the first electrode and the reflective layer is greater than or equal to 100 degrees and less than or equal to 170 degrees.

8. The semiconductor chip according to claim 6, wherein the first electrode is disposed on a bottom surface of the first-type semiconductor layer and a bottom surface of the filling layer and is connected to the reflective layer.

9. The semiconductor chip according to claim 1, wherein in the cross-sectional view, the semiconductor unit has a first width and a second width respectively on the first side and the second side, and the second width is greater than the first width.

10. The semiconductor chip according to claim 1, wherein a material of the reflective layer comprises silver, aluminum, tin, indium, gold or a combination of the above.

11. A semiconductor device, comprising:
a circuit substrate comprising a first pad and a second pad; and
a semiconductor chip disposed on the circuit substrate and comprising:
a semiconductor unit comprising:
a semiconductor die comprising a first-type semiconductor layer, an active layer and a second-type semiconductor layer stacked in sequence; and
a filling layer surrounding the semiconductor die;
a first electrode disposed on a first side of the semiconductor unit and electrically connected to the first-type semiconductor layer;
a second electrode disposed on a second side of the semiconductor unit and electrically connected to the second-type semiconductor layer, wherein a material of the second electrode comprises a transparent conductive material; and
a reflective layer disposed on a side surface of the filling layer, wherein in a cross-sectional view, the side surface of the filling layer is connected to a top surface of the filling layer;
wherein the first pad is electrically connected to the first electrode and the second pad is electrically connected to the second electrode.

12. The semiconductor device according to claim 11, further comprising:
at least one light-converging element disposed on the circuit substrate and located above the semiconductor chip.

13. The semiconductor device according to claim 12, further comprising:
a unit defining layer located on the circuit substrate and has a first opening, wherein the semiconductor chip is located in the first opening.

14. The semiconductor device according to claim 13, wherein the first pad and the second pad are located in the first opening, the second electrode is further disposed on a top surface of the filling layer, and the second electrode is electrically connected to the second pad through the reflective layer.

15. The semiconductor device according to claim 13, wherein the first pad is located in the first opening, and the unit defining layer further has a third opening that partially exposes the second pad, the semiconductor device further comprises a connecting wire located on the unit defining layer and in the third opening, and the second electrode is electrically connected to the second pad through the connecting wire.

16. The semiconductor device according to claim 13, wherein the at least one light-converging element comprises:
a bank layer located on the unit defining layer and has a second opening that overlaps the first opening.

17. The semiconductor device according to claim 16, wherein the at least one light-converging element comprises a lens element, and the lens element is disposed above the bank layer and the semiconductor chip.

18. The semiconductor device according to claim 13, wherein the at least one light-converging element comprises a reflective cup element, and the reflective cup element is disposed above the unit defining layer and the semiconductor chip.

19. The semiconductor device according to claim 18, wherein a surface of the reflective cup element facing the semiconductor chip has a cavity overlapping the semiconductor chip.

20. The semiconductor device according to claim 18, wherein the at least one light-converging element further comprises a lens element, and the lens element is disposed on the reflective cup element.
